(19) United States
(12) Patent Application Publication
(10) Pub. No.: US 2025/0261346 A1
(43) Pub. Date: Aug. 14, 2025

(54) COOLING STRUCTURE FOR IN-VEHICLE EQUIPMENT

(71) Applicant: Toyota Jidosha Kabushiki Kaisha, Toyota-shi (JP)

(72) Inventor: Masayuki SUGITA, Nagakute-shi (JP)

(73) Assignee: Toyota Jidosha Kabushiki Kaisha, Toyota-shi (JP)

(21) Appl. No.: 18/947,202

(22) Filed: Nov. 14, 2024

(30) Foreign Application Priority Data
Feb. 8, 2024 (JP) 2024-018122

(51) Int. Cl. H05K 7/20

(52) U.S. Cl. CPC H05K 7/20872

(57) ABSTRACT

A cooling structure for in-vehicle equipment includes in-vehicle equipment including a heat generating portion, and being placed in a predetermined space of a vehicle, and a coolant channel provided in a casing of the in-vehicle equipment. The casing has a heat receiving portion that faces in close proximity an external heat source in a state of being placed in the space, and in which heat of the external heat source is transferred and temperature rises. The coolant channel has a cooling channel being in contact with or close to the heat generating portion and cooling the heat generating portion by the coolant, and a thermally insulating channel that communicates with the cooling channel and in which the coolant flows continuously with the cooling channel, and is in contact with or close to the heat receiving portion and blocks or suppresses heat transfer from the external heat source by the coolant.

### CROSS-REFERENCE TO RELATED APPLICATION

This application claims priority to Japanese Patent Application No. 2024-018122 filed on Feb. 8, 2024, incorporated herein by reference in its entirety.

### BACKGROUND

### 1. Technical Field

The present disclosure relates to a cooling structure for cooling equipment or a device that generates heat and of which temperature rises, and more particularly, relates to a cooling structure for cooling in-vehicle equipment such as an inverter, a converter, or the like, installed in a vehicle.

### 2. Description of Related Art

Japanese Unexamined Patent Application Publication No. 2022-41224 (JP 2022-41224 A) describes a power converting device (inverter) designed to efficiently cool a smoothing capacitor. The power converting device described in JP 2022-41224 A includes a capacitor element for smoothing direct current electric power, and a metal case having an accommodation portion for accommodating the capacitor element and a coolant channel. The power conversion device further includes potting resin that fills a gap between the capacitor element and the accommodation portion. A portion of the accommodation portion is filled with the potting resin, and a pool for adjusting height of an exposed surface of the potting resin is formed. Also, the coolant channel is formed on a bottom face side of the accommodation portion in the casing of the metal case.

Also, WO 2014/147961 describes an electronic equipment cooling device having a cuboid casing in which components that generate heat are built in, and a power conversion device (converter) including the same. In the electronic equipment cooling device and the power conversion device described in WO 2014/147961, a plate-shaped partition portion is disposed inside a chamber, inclined so as to distribute a desired coolant flow rate corresponding to a heat generation ratio of the chamber between two faces adjacent to each other and orthogonal to each other of the cuboid casing. Thus, the two faces (bottom face and wall face) of the casing that are adjacent to each other and orthogonal to each other, are efficiently cooled. As a specific example of the power conversion device, WO 2014/147961 describes a configuration in which the coolant channel is provided on the bottom face and the wall face.

### SUMMARY

The power conversion devices described in JP 2022-41224 A and WO 2014/147961 described above are cooling structures for cooling a power conversion device such as an inverter, a converter, or the like, with a coolant channel being provided inside a casing such as a metal case or the like. Causing coolant to circulate through the coolant channel enables the components and equipment disposed in the casing to be efficiently cooled. However, the cooling structures described in JP 2022-41224 A and WO 2014/147961 do not take into consideration effects of external thermal interference, i.e., heat transferred from outside of the device. Accordingly, there is a possibility that cooling performance will be insufficient with the above-described coolant channel alone, and that the components and equipment that generate heat in the casing cannot be sufficiently cooled.

For example, in-vehicle equipment such as inverters, converters, and so forth, installed in a hybrid electric vehicle or a battery electric vehicle often use semiconductors, magnetic components, and so forth, that generate heat. Accordingly, applying the cooling structure (coolant channel) such as described in the above JP 2022-41224 A and WO 2014/147961 enables the in-vehicle equipment of which the temperature rises to be cooled. However, there are cases in which such in-vehicle equipment may be placed in close proximity to other components or devices that become hot, such as for example, motors, engines, other high voltage equipment, engine exhaust systems, or the like. That is to say, there are cases in which the in-vehicle equipment is disposed in close proximity to, or adjacent to, external heat sources. Accordingly, there is a possibility that the temperature of in-vehicle equipment such as inverters, converters, or the like, will rise due to transfer of heat from an external heat source, in addition to the temperature rise caused by its own heat generation. In order to suppress heat transfer from such an external heat source, i.e., to suppress external thermal interference, measures such as disposing the heat source so as to be sufficiently distanced from the external heat source, installing an insulator or thermally insulating material, or the like, are conceivable. However, each of these measures leads to increase in the size of the device or the installation space thereof, complication of the configuration, increase in the number of parts, or the like.

This disclosure has been conceived in view of the above-described technical problems, and provides a cooling structure of in-vehicle equipment that is capable of obtaining sufficient cooling performance with a simple configuration, without increasing the size of the device or the installation space.

To achieve the above object, this disclosure is a cooling structure for in-vehicle equipment, the cooling structure including in-vehicle equipment that includes a heat generating portion of which temperature rises when running, and that is placed in a predetermined space of a vehicle, and a coolant channel provided in a casing of the in-vehicle equipment, for circulating a coolant for cooling the heat generating portion, in which
the casing includes a heat receiving portion that faces in close proximity a predetermined external heat source in a state of being placed in the space, and to which heat of the external heat source is transmitted and temperature rises and,
the coolant channel includes a cooling channel that is in contact with or close to the heat generating portion and that cools the heat generating portion by the coolant, and a thermally insulating channel that communicates with the cooling channel and through which the coolant flows continuously with the cooling channel, and also is in contact with or close to the heat receiving portion, and that blocks or suppresses heat transfer from the external heat source by the coolant.

Also, the cooling channel according to this disclosure may be disposed so as to be in contact with or close to the heat generating portion at another portion different from the heat receiving portion in the casing, and
the thermally insulating channel according to this disclosure is disposed so as to be in contact with or close to the heat receiving portion, by facing an inner wall face (inner side of the casing) of the heat receiving portion.

Also, the coolant channel according to this disclosure may include a cooling and thermally insulating channel that communicates with at least one of the cooling channel and the thermally insulating channel, through which the coolant flows continuing to at least one of the cooling channel and the thermally insulating channel, that also cools the heat generating portion by the coolant by being in contact with or close to the heat generating portion, and that also blocks or suppresses heat transfer from the external heat source by the coolant by being in contact with or close to the heat receiving portion, and
the cooling and thermally insulating channel according to this disclosure may include a cooling face facing the heat generating portion, and a thermally insulating face facing the heat receiving portion, with the cooling face being disposed in contact with or close to the heat generating portion, and also the thermally insulating face being disposed facing the inner wall face so as to be in contact with or close to the heat receiving portion.

The coolant channel in this disclosure may also include an inlet through which the coolant flows into the coolant channel, and an outlet through which the coolant flows out from the coolant channel, and
this disclosure may be configured such that the coolant of which a temperature is equivalent to or no higher than that of the coolant flowing out from the outlet is caused to flow into the coolant channel from the inlet.

The cooling structure of the in-vehicle equipment according to this disclosure cools in-vehicle equipment such as inverters, converters, alternating current chargers, or the like, that are installed in hybrid electric vehicles or battery electric vehicles, for example. Such in-vehicle equipment uses a great number of semiconductors and magnetic components that generate heat, and accordingly the temperature rises when running. Accordingly, the cooling structure of the in-vehicle equipment according to this disclosure includes a coolant channel for cooling heat generating portions such as semiconductors and magnetic components. The coolant channel cools the heat generating portion by coolant flowing through the cooling channel in the same way as in the related art. Further, the coolant channel includes a thermally insulating channel together with the cooling channel. The thermally insulating channel is provided in a heat receiving portion facing an external heat source, such as an engine, a motor, or the like, for example, and blocks heat transferred from the external heat source to casing of the in-vehicle equipment. In short, the coolant channel in the cooling structure of the in-vehicle equipment according to this disclosure is made up of a cooling channel and a thermally insulating channel, and has a cooling function of cooling the heat generating portion, and a thermal insulation function of thermally insulating between the external heat source and the in-vehicle equipment. Accordingly, thermal insulation of the external heat source can also be performed when cooling the heat generating portion, and thus the cooling performance of the cooling structure can be improved. Also, the coolant channel and the thermally insulating channel in the cooling channel communicate with each other, and are configured to continuously circulate the same coolant, and accordingly can be easily configured without significantly changing the conventional cooling structure (configuration having only the cooling channel). As described above, since the coolant channel also serves as thermal insulation from external heat sources in addition to cooling of the heat generating portions, space for thermal insulation, and thermally insulating material such as insulators and so forth, are unnecessary. Accordingly, the in-vehicle equipment can be reduced in size and simplified. Consequently, installation space of the in-vehicle equipment can be secured, and the degree of freedom in installation layout can be increased.

Thus, according to the cooling structure of the in-vehicle equipment of this disclosure, sufficient cooling performance for cooling the in-vehicle equipment can be obtained without increasing the size of the device and the installation space, and with a simple configuration as well. Further, along with improvement in cooling performance, the size of the in-vehicle equipment, can be reduced, and consequently, an in-vehicle equipment can be configured that has good vehicular installability.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating an example (a basic configuration example) of a cooling structure of an in-vehicle equipment targeted in the present disclosure;

FIG. 2 is a diagram illustrating another example of a cooling structure (a configuration example corresponding to two external heat sources) of an in-vehicle equipment targeted in the present disclosure;

FIG. 3 is a diagram illustrating another example of a cooling structure of an in-vehicle equipment (a configuration example in which a heat generating portion in contact with two surfaces of a cooling channel is cooled) which is an object of the present disclosure;

FIG. 4 is a diagram illustrating another example of a cooling structure of an in-vehicle equipment (an example of a configuration corresponding to three external heat sources) according to the present disclosure; and

FIG. 5 is a diagram illustrating another example of a cooling structure (a configuration example of cooling a heat generating portion having a substrate shape) of an in-vehicle equipment to be covered by the present disclosure.

### DETAILED DESCRIPTION OF EMBODIMENTS

Embodiments of the present disclosure will be described with reference to the drawings. It should be noted that the embodiments described below are merely examples of a case where the present disclosure is embodied, and the present disclosure is not limited thereto.

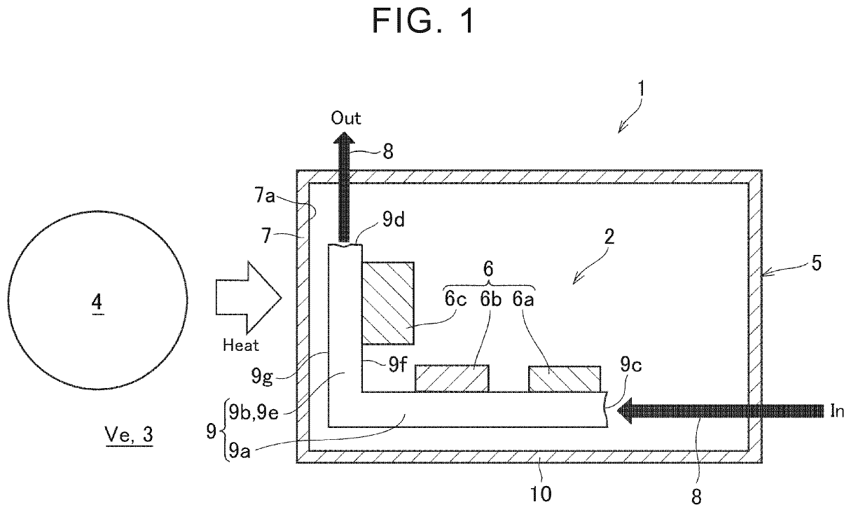

The in-vehicle equipment according to the embodiment of the present disclosure is directed to machines and devices installed in a vehicle. The in-vehicle equipment has a heat generating portion such as a semiconductor or a magnetic component that generates heat. In addition, when installed in a vehicle, for example, the vehicle is placed adjacent to or in proximity to an external heat source such as an engine or a motor. Therefore, the in-vehicle equipment has a heat receiving portion in which heat is transferred from an external heat source and the temperature is increased by being brought close to the external heat source in a state of being placed on the vehicle. In addition, the cooling structure of the in-vehicle equipment according to the embodiment of the present disclosure is configured to cool the above-described heat generating portion and thermal insulation of the heat transferred to the heat receiving portion. An example of a cooling structure of such an in-vehicle equipment is shown in FIG. 1.

The in-vehicle equipment 1 shown in FIG. 1 and the cooling structure 2 thereof are placed in a predetermined space 3 in the vehicle Ve. The vehicle Ve is not limited to a particular type. For example, a conventional engine vehicle using an engine as a driving force source, a hybrid electric vehicle using an engine and a motor as a driving force source, or a battery electric vehicle using a motor as a driving force source (both not shown) may be used. The space 3 in this case is, for example, an engine compartment (not shown), a battery space (not shown), a luggage compartment (not shown), or the like. An external heat source 4 is provided in the space 3, and the in-vehicle equipment 1 is placed in the vicinity of the external heat source 4. The external heat source 4 is, for example, an engine (not shown), a motor (not shown), or an exhaust system (not shown) of the engine, or other parts or machines or devices that generate heat and become high in temperature. The external heat source 4 is installed in the space 3, and exerts a heat effect on the in-vehicle equipment 1 which is close to or adjacent to the space 3. The “other in-vehicle equipment” having the heat generating portion 6 described later may also be the external heat source 4 in the embodiment of the present disclosure when the device is placed adjacent to or close to the in-vehicle equipment 1 in the space 3.

The in-vehicle equipment 1 is a machine or a device placed in the predetermined space 3 of the vehicle Ve as described above, and is, for example, an inverter (not shown) installed in a hybrid electric vehicle or a battery electric vehicle, a converter (not shown), an AC charger (not shown), or the like. The in-vehicle equipment 1 according to the embodiment of the present disclosure includes a casing 5, a heat generating portion 6, and a heat receiving portion 7.

The casing 5 is a member that forms an outer shell of the in-vehicle equipment 1. That is, the casing 5 is a case or a housing of the in-vehicle equipment 1 that accommodates devices, components, and the like (not shown) constituting the in-vehicle equipment 1. The shape of the casing 5 is arbitrary, and is not limited to a specific shape or size. FIG. 1 shows, as an example, a rectangular cross-section of a rectangular parallelepiped casing 5.

The heat generating portion 6 is a device, a component, or a portion of the device, the component, or the like constituting the in-vehicle equipment 1, which generates heat by itself during operation and whose temperature rises. The heat generating portion 6 is a “cooled portion” which is cooled by the cooling structure 2 described later. For example, a component constituting an inverter, a converter, or the like, and a semiconductor such as a capacitor or a resistor, a magnetic component such as a coil or a reactor, or the like corresponds to the heat generating portion 6. As described above, the heat generating portion 6 is accommodated in a predetermined position in the casing 5. The type, shape, and quantity of the heat generating portion 6 are arbitrary, and are not limited to specific types, shapes, quantities, and the like. FIG. 1 shows an embodiment in which three heat generating portions 6 are provided, i.e., a heat generating portion 6a, a heat generating portion 6b, and a heat generating portion 6c.

The heat receiving portion 7 is a portion of the casing 5, and is a portion where the heat of the external heat source 4 is transferred and the temperature rises. As described above, the in-vehicle equipment 1 in the disclosed embodiment is placed in the space 3 of the vehicle Ve close to or adjacently to the external heat source 4. Therefore, in the casing 5, there is a portion that faces the external heat source 4 in a state of being placed in the space 3, and the heat of the external heat source 4 is transferred to increase the temperature. A portion of the casing 5 facing the external heat source 4 serves as a heat receiving portion 7.

As described above, the in-vehicle equipment 1 according to the embodiment of the present disclosure includes the heat generating portion 6 that generates heat by itself and increases in temperature, and the heat receiving portion 7 that increases in temperature by the heat transferred from the external heat source 4. Therefore, the cooling structure 2 according to the embodiment of the present disclosure is configured to have a cooling function of cooling the heat generating portion 6 and a heat insulating function of thermally insulating the heat of the heat receiving portion 7. To this end, the cooling structure 2 is provided with a coolant channel 9 through which a predetermined coolant 8 circulates. The type of the coolant 8 is arbitrary, and is not limited to a specific one. For example, water, coolant liquid, oil, air, or the like may be applied as the coolant 8.

The coolant channel 9 is formed of at least two types of channels, namely, a cooling channel 9a and a thermally insulating channel 9b. The cooling channel 9a and the thermally insulating channel 9b are in communication with each other. The coolant channel 9 has an inlet 9c through which the coolant 8 flows into the coolant channel 9, and an outlet 9d through which the coolant 8 flows out of the coolant channel 9. In the embodiment illustrated in FIG. 1, an inlet 9c is provided in the cooling channel 9a, and an outlet 9d is provided in the thermally insulating channel 9b. Therefore, the coolant 8 continuously flows from the cooling channel 9a toward the thermally insulating channel 9b between the cooling channel 9a and the thermally insulating channel 9b.

The cooling channel 9a is disposed in the casing 5 so as to be in contact with or close to the heat generating portion 6. Further, the cooling channel 9a is disposed in the casing 5 so as to be in contact with or close to the heat generating portion 6 at another portion (in the case shown in FIG. 1, in the vicinity of the bottom portion 10 of the casing 5) that differs from the heat receiving portion 7. Therefore, the cooling channel 9a cools the heat generating portion 6 by the coolant 8 circulating therethrough. In the embodiment illustrated in FIG. 1, the cooling channel 9a is disposed so as to be contacted with the heat generating portion 6a and the heat generating portion 6b. Therefore, the heat generating portion 6a and the heat generating portion 6b are cooled by transferring the heat of the heat generating portion 6a and the heat generating portion 6b to the coolant 8 flowing through the cooling channel 9a.

The thermally insulating channel 9b is disposed in the casing 5 so as to face the inner wall surface 7a of the heat receiving portion 7 and to be contacted with or close to the inner wall surface 7a thereof. Therefore, the thermally insulating channel 9b blocks or suppresses heat transfer from the external heat source 4 by the coolant 8 circulating inside. In the embodiment illustrated in FIG. 1, the thermally insulating channel 9b faces the inner wall surface 7a of the heat receiving portion 7 and is disposed close to the inner wall surface 7a thereof. Therefore, the thermally insulating channel 9b thermally insulates the heat transferred from the external heat source 4 to the casing 5 through the heat receiving portion 7 and the inner wall surface 7a. Therefore, an increase in temperature in the casing 5 and the casing 5 can be suppressed due to the influence of heat from the external heat source 4. Thereby, the cooling performance of the in-vehicle equipment 1 by the cooling structure 2 is improved.

Further, the cooling structure 2 in the disclosed embodiment is configured such that the coolant 8 having a temperature equal to or lower than the temperature of the coolant 8 flowing out from the outlet 9d of the coolant channel 9 flows into the coolant channel 9 from the inlet 9c. For example, a heat exchanger (not shown) such as a radiator or an oil cooler is provided to cool the coolant 8 flowing out of the outlet 9d. As a result, the coolant 8 having a lower temperature (higher cooling effectiveness) than the coolant 8 flowing out from the outlet 9d is supplied from the inlet 9c to the coolant channel 9. The heat generating portions 6a, 6b, 6c are arranged such that the inlet 9c of the coolant channel 9 is closer to the heat generating portion 6 having a larger heat generation value. Alternatively, the shapes and arrangements of the coolant channel 9 (the cooling channel 9a and the thermally insulating channel 9b) are determined with respect to the positions of the respective heat generating portions 6a, 6b, 6c.

In the embodiment illustrated in FIG. 1, the three heat generating portions 6a, 6b, 6c are the heat generating portion 6a, the heat generating portion 6b, and the heat generating portion 6c in descending order of the heat generation amount. Therefore, the heat generating portions 6a, 6b, 6c are positioned in the order of the heat generating portion 6a, the heat generating portion 6b, and the heat generating portion 6c from a position close to the inlet 9c. Therefore, the lower-temperature coolant 8 can be supplied to the heat generating portion 6 whose heat generation value is large and whose temperature is high, and the heat generating portions 6a, 6b, 6c can be cooled efficiently.

In addition, in the embodiment illustrated in FIG. 1, the thermally insulating channel 9b faces the inner wall surface 7a of the heat receiving portion 7 and is disposed so as to be contacted with the heat generating portion 6c. That is, the thermally insulating channel 9b is a cooling and thermally insulating channel 9e in the disclosed embodiment.

The cooling and thermally insulating channel 9e has a cooling surface 9f facing the heat generating portion 6c and a heat insulating surface 9g facing the inner wall surface 7a of the heat receiving portion 7. The cooling and thermally insulating channel 9e is arranged such that the cooling surface 9f is in contact with or close to the heat receiving portion 7, and the heat insulating surface 9g is in contact with or close to the heat receiving portion 7 so as to face the inner wall surface 7a of the heat receiving portion 7. In the embodiment illustrated in FIG. 1, in the cooling and thermally insulating channel 9e, the cooling surface 9f contacts the heat receiving portion 7, and the heat insulating surface 9g faces and approaches the inner wall surface 7a of the heat receiving portion 7.

Then, the cooling and thermally insulating channel 9e communicates with at least one of the cooling channel 9a and the thermally insulating channel 9b, and the coolant 8 flows continuously with at least one of the cooling channel 9a and the thermally insulating channel 9b. In addition, the cooling and thermally insulating channel 9e cools the heat generating portion 6 by the coolant 8 in contact with or close to the heat generating portion 6, and blocks or suppresses heat transfer from the external heat source 4 by the coolant 8 in contact with or close to the heat receiving portion 7. In the embodiment illustrated in FIG. 1, the cooling and thermally insulating channel 9e also serves as a thermally insulating channel 9b, and communicates with the cooling channel 9a, and the coolant 8 flows continuously with the cooling channel 9a. Further, the cooling and thermally insulating channel 9e contacts the heat generating portion 6c to cool the heat generating portion 6c by the coolant 8, and blocks or suppresses the heat transfer from the external heat source 4 by the coolant 8 close to the inner wall surface 7a of the heat receiving portion 7.

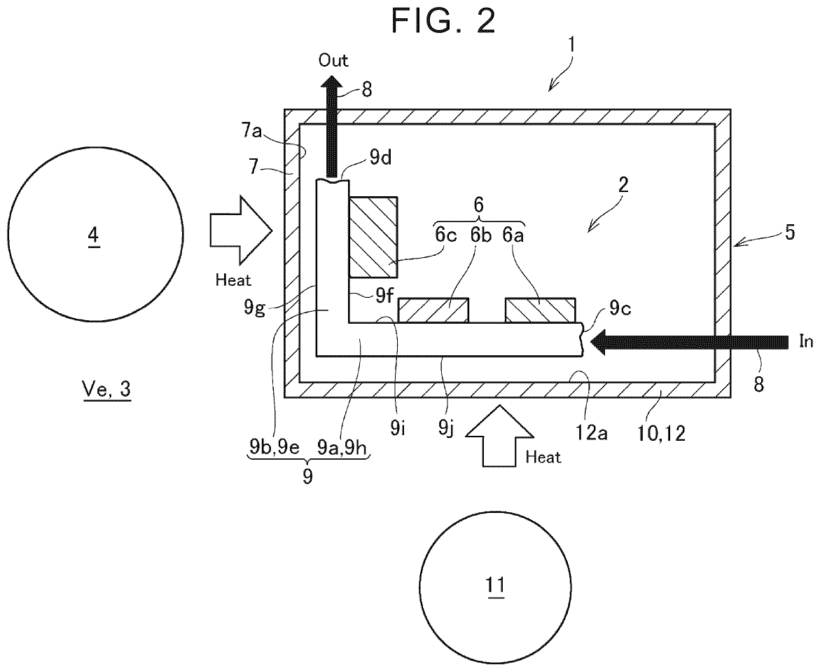

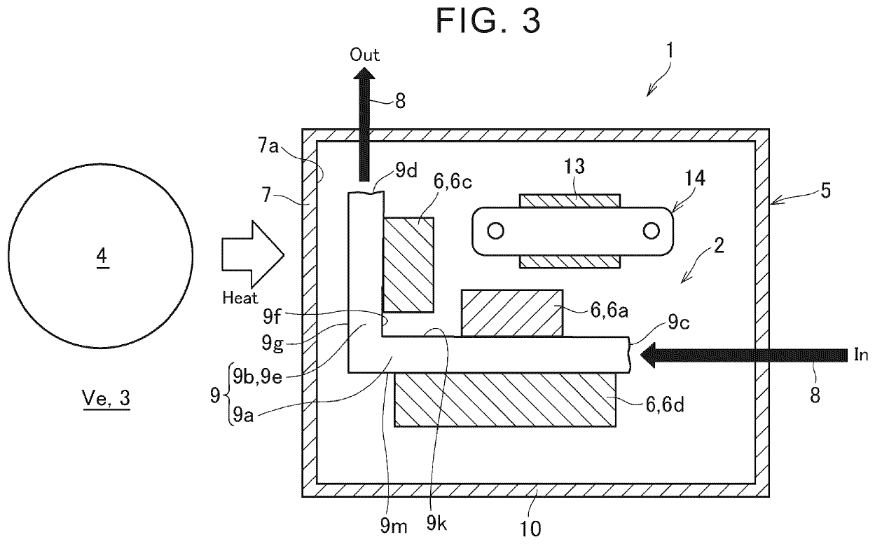

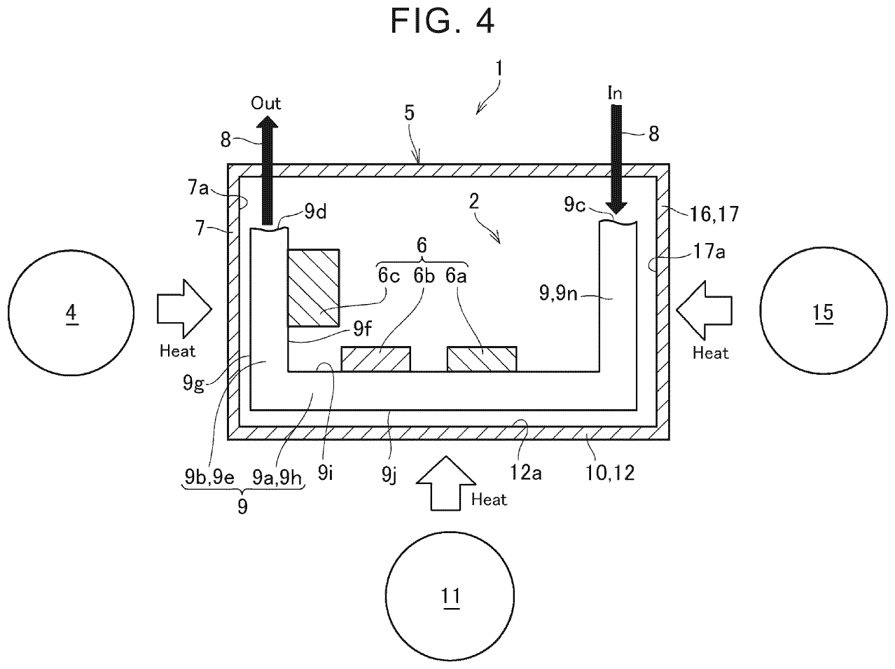

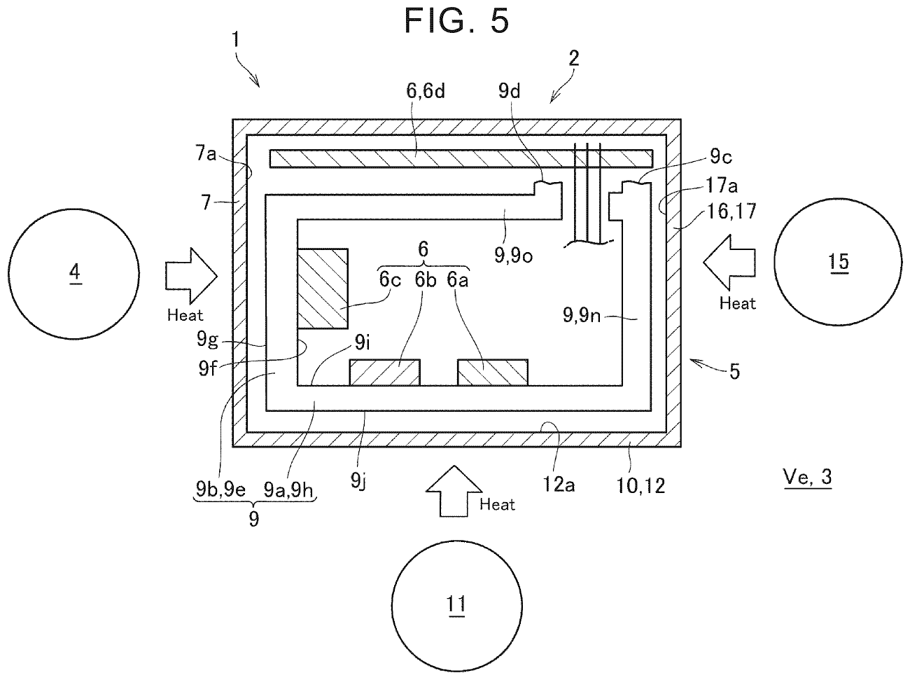

Note that the shapes and types of the coolant channel 9 (the cooling channel 9a, the thermally insulating channel 9b, and the cooling and thermally insulating channel 9e) are optional, and are not limited to a particular one. For example, a configuration in which a pipe-shaped channel is piped or a configuration in which a hollow flat-plate-shaped channel is assembled may be applied. FIG. 1 and FIG. 2, FIG. 3, FIG. 4, FIG. 5 described later show an image in which the coolant channel 9 (the cooling channel 9a, the thermally insulating channel 9b, and the cooling and thermally insulating channel 9e) is formed by a pipe-shaped member.

FIG. 2, FIG. 3, FIG. 4, and FIG. 5 show another configuration example of the cooling structure 2 in the embodiment of the present disclosure. In FIG. 2, FIG. 3, FIG. 4, and FIG. 5, the same reference numerals as those used in FIG. 1 or the previously described drawings denote the same members or parts having the same configuration and function as those of the cooling structure 2 shown in FIG. 1 or the previously described drawings in the cooling structure 2.

The cooling structure 2 shown in FIG. 2 is configured to correspond to the external heat source 4 and the “two external heat sources” of the external heat source 11. The external heat source 11, like the external heat source 4 described above, is, for example, an engine, a motor, or an exhaust system of an engine, or other components or machines or devices that generate heat and become high in temperature. In the example illustrated in FIG. 2, the in-vehicle equipment 1 is placed at a position where the bottom portion 10 of the casing 5 faces and is close to the external heat source 11. Therefore, in the example shown in FIG. 2, the bottom portion 10 of the casing 5 is a heat receiving portion 12 which is opposed to the external heat source 11 and which is configured to transfer the heat of the external heat source 11 and raise the temperature.

Further, in the cooling structure 2 shown in FIG. 2, since the bottom portion 10 of the casing 5 serves as the heat receiving portion 12 as described above, the cooling channel 9a serves as the cooling and thermally insulating channel 9h in the disclosed embodiment. Therefore, similarly to the cooling and thermally insulating channel 9e described above, the cooling and thermally insulating channel 9h has the cooling surface 9i facing the heat generating portion 6a, 6b and the heat insulating surface 9j facing the inner wall surface 12a of the heat receiving portion 12. In the embodiment illustrated in FIG. 2, the cooling and thermally insulating channel 9h also serves as a cooling channel 9a, and communicates with the thermally insulating channel 9b (the cooling and thermally insulating channel 9e), and the coolant 8 flows continuously with the thermally insulating channel 9b (the cooling and thermally insulating channel 9e). In addition, the cooling and thermally insulating channel 9h contacts the heat generating portion 6a, 6b to cool the heat generating portion 6a, 6b by the coolant 8, and blocks or suppresses heat transfer from the external heat source 11 by the coolant 8 close to the inner wall surface 12a of the heat receiving portion 12.

In the cooling structure 2 shown in FIG. 3, the coolant channel 9 are provided on two opposite surfaces of the cooling channel 9a so as to be in contact with or close to the heat generating portion 6, respectively. In the embodiment illustrated in FIG. 3, the cooling channel 9a is arranged such that the upper surface 9k of the cooling channel 9a is in contact with the heat generating portion 6a, and the lower surface 9m of the cooling channel 9a is in contact with the heat generating portion 6d.

In the example shown in FIG. 3, the casing 5 is provided with another heat generating portion 13 different from the cooling structure 2 and another cooling equipment 14 for cooling the heat generating portion 13.

The cooling structure 2 shown in FIG. 4 is configured to correspond to “three external heat sources” of the external heat source 4, the external heat source 11, and the external heat source 15. The external heat source 15, like the external heat sources 4 and 11 described above, is, for example, an engine, a motor, or an exhaust system of an engine, or other parts or machines or devices that generate heat and become high in temperature. In the example illustrated in FIG. 4, the in-vehicle equipment 1 is placed at a position where the right side portion 16 of the casing 5 faces and is close to the external heat source 15. Therefore, in the example shown in FIG. 4, the right side portion 16 of the casing 5 is a heat receiving portion 17 that is opposed to the external heat source 15 and that is configured to transfer the heat of the external heat source 15 to increase the temperature.

In the cooling structure 2 shown in FIG. 4, corresponding to the right side portion 16 of the casing 5 serving as the heat receiving portion 17 as described above, the thermally insulating channel 9n that faces the inner wall surface 17a of the heat receiving portion 17 and contacts or is close to the inner wall surface 17a is provided. The thermally insulating channel 9n thermally insulates the heat transferred from the external heat source 15 into the casing 5 through the heat receiving portion 17 and the inner wall surface 17a.

The cooling structure 2 shown in FIG. 5 corresponds to the three external heat sources 4, 11, and 15, and is configured to cool the plate-shaped heat generating portion 6d. The heat generating portion 6d is, for example, a flat-plate-shaped “board” in which a large number of electronic components and semiconductors are incorporated.

In the cooling structure 2 shown in FIG. 5, a cooling channel 9o for cooling the heat generating portion 6d as described above is provided. The cooling channel 9o is communicated with the downstream side (upper side in FIG. 5) of the thermally insulating channel 9b (the cooling and thermally insulating channel 9e), and is arranged in the direction (right side in FIG. 5) of the thermally insulating channel 9n in parallel with the cooling channel 9a (the cooling and thermally insulating channel 9h). An outlet 9d is provided at an end portion (right end in FIG. 5) of the cooling channel 9o. Therefore, the coolant 8 flows continuously from the thermally insulating channel 9n through the cooling channel 9a (the cooling and thermally insulating channel 9h), the thermally insulating channel 9b (the cooling and thermally insulating channel 9e), and the cooling channel 9o so as to surround the inner peripheral part of the casing 5.

As described above, the cooling structure of the in-vehicle equipment according to the embodiment of the present disclosure includes the coolant channel 9 for cooling the heat generating portion 6 such as a semiconductor or a magnetic component. The coolant channel 9 includes, for example, a cooling channel 9a and a thermally insulating channel 9b, and has a cooling function of cooling the heat generating portion 6 and a heat insulating function of thermally insulating between the external heat source 4 and the in-vehicle equipment 1. Therefore, when the heat generating portion 6 is cooled, thermal insulation of the external heat source 4 can also be performed, so that the cooling performance of the cooling structure 2 can be improved. Further, the cooling channel 9a and the thermally insulating channel 9b in the coolant channel 9 are communicated with each other, and are configured to continuously circulate the same coolant 8, so that they can be easily configured. As described above, since the coolant channel 9 serves also as thermal insulation from the external heat source 4 in addition to the cooling of the heat generating portion 6, a space for thermal insulation and a thermally insulating material such as an insulator are not required. Therefore, the in-vehicle equipment 1 can be miniaturized and simplified. As a result, it is possible to secure the installation space of the in-vehicle equipment 1 and to increase the degree of freedom of the installation layout.

Therefore, according to the cooling structure of the in-vehicle equipment according to the embodiment of the present disclosure, it is possible to obtain sufficient cooling performance for cooling the in-vehicle equipment 1 with a simple configuration without increasing the size of the device and the installation space. In addition, along with the improvement in the cooling performance, the in-vehicle equipment 1 can be downsized, and consequently, the in-vehicle equipment 1 with good installability on the vehicle Ve can be configured.

What is claimed is:

1. A cooling structure for in-vehicle equipment, the cooling structure comprising:
in-vehicle equipment that includes a heat generating portion of which temperature rises when running, and that is placed in a predetermined space of a vehicle; and
a coolant channel provided in a casing of the in-vehicle equipment, for circulating a coolant for cooling the heat generating portion, wherein:
the casing includes a heat receiving portion that faces in close proximity a predetermined external heat source in a state of being placed in the space, and to which heat of the external heat source is transmitted and temperature rises; and
the coolant channel includes a cooling channel that is in contact with or close to the heat generating portion and that cools the heat generating portion by the coolant, and a thermally insulating channel that communicates with the cooling channel and through which the coolant flows continuously with the cooling channel, and also is in contact with or close to the heat receiving portion, and that blocks or suppresses heat transfer from the external heat source by the coolant.

2. The cooling structure according to claim 1, wherein:
the cooling channel is disposed so as to be in contact with or close to the heat generating portion at another portion different from the heat receiving portion in the casing; and
the thermally insulating channel is disposed so as to be in contact with or close to the heat receiving portion, by facing an inner wall face of the heat receiving portion.

3. The cooling structure according to claim 2, wherein:
the coolant channel includes a cooling and thermally insulating channel that communicates with at least one of the cooling channel and the thermally insulating channel, through which the coolant flows continuing to at least one of the cooling channel and the thermally insulating channel, that also cools the heat generating portion by the coolant by being in contact with or close to the heat generating portion, and that also blocks or suppresses heat transfer from the external heat source by the coolant by being in contact with or close to the heat receiving portion; and
the cooling and thermally insulating channel includes a cooling face facing the heat generating portion, and a thermally insulating face facing the heat receiving portion, with the cooling face disposed in contact with or close to the heat generating portion, and also the thermally insulating face being disposed facing the inner wall face so as to be in contact with or close to the heat receiving portion.

4. The cooling structure according to claim 1, wherein:
the coolant channel includes an inlet from which the coolant flows into the coolant channel, and an outlet from which the coolant flows out from the coolant channel; and
the coolant of which a temperature is equivalent to or no higher than that of the coolant flowing out from the outlet is caused to flow into the coolant channel from the inlet.
